(19) United States
(12) Patent Application Publication
(10) Pub. No.: US 2015/0170878 A1
(43) Pub. Date: Jun. 18, 2015

(54) DRAWING APPARATUS, DRAWING METHOD AND MANUFACTURING METHOD OF ARTICLE

(71) Applicant: CANON KABUSHIKI KAISHA, Tokyo (JP)

(72) Inventor: Yusuke Sugiyama, Kawasaki-shi (JP)

(21) Appl. No.: 14/563,553

(22) Filed: Dec. 8, 2014

(30) Foreign Application Priority Data
Dec. 18, 2013 (JP) 2013-261508

(51) Int. Cl. H01J 37/317

(52) U.S. Cl. CPC H01J 37/3178; H01J 2237/063; H01J 2237/317; H01J 2237/15

(57) ABSTRACT

A drawing apparatus includes a detection unit which detects defective beam and a control unit which controls irradiation with normal beam and the irradiation position in the sub-scanning direction. The control unit controls the irradiation such that, in accordance with a detection result of the detection unit, a normal beam is irradiated instead of the defective beam at a position that has been planned to be irradiated with the defective beam by changing an amount of change in the irradiation positions of the plurality of beams from the predetermined amount and, in a case in which the detection unit stops detecting the defective beam, the amount of change in the irradiation position of the plurality of beams is restored to the predetermined amount.

### BACKGROUND OF THE INVENTION

1. Field of the Invention

One disclosed aspect of the embodiments relates to a drawing apparatus, a drawing method and a manufacturing method of an article.

2. Description of the Related Art

A drawing apparatus configured to irradiate a wafer with a plurality of beams simultaneously in order to form a latent image of a desired pattern on the wafer has been proposed. However, if there is a defective beam that is not able to irradiate the wafer with a desired amount of energy due to a defective member related to irradiation control of the beam, a latent image that has been planned to be formed is not able to be formed in an area that has been planned to be irradiated with the defective beam. Thus, in a drawing apparatus which irradiates a plurality of beams, there is a problem that, if at least one defective beam is caused, it is not possible to form a latent image of a desired pattern.

PCT Japanese Translation Patent Publication No. 2009-503844 about an electron beam drawing apparatus describes a technique to relatively scan a wafer and an optical system so that an area which has not been able to be irradiated due to a defective beam is compensated by being irradiated with a normal beam.

As a specific example, a method is described in which, after drawing is performed on a wafer in a sub-scanning direction, the wafer is moved slightly in a main scanning direction which crosses perpendicularly the sub-scanning direction, and then drawing is performed in the opposite direction in the sub-scanning direction. The wafer is moved in the main scanning direction in order to perform compensation drawing with the normal beam which can irradiate the area that has not been able to be irradiated due to the defective beam, and a moving amount of the wafer is very small. Therefore, scanned regions in the sub-scanning direction by an optical system before and after the wafer is moved in the main scanning direction overlap for the most part.

The technique to compensate for the drawing by irradiating, with the normal beam instead of the defective beam, a position that has been planned to be irradiated with the defective beam as described in PCT Japanese Translation Patent Publication No. 2009-503844 means that the optical system scans almost all the areas on the wafer twice in an overlapping manner. Therefore, throughput may decrease even to compensate for the irradiation by a single defective beam.

### SUMMARY OF THE INVENTION

One disclosed aspect of the embodiments relates to a drawing apparatus capable of reducing a decrease in throughput in a case in which irradiation of a defective beam is compensated and a latent image of a pattern is formed.

A drawing apparatus is an apparatus which draws a pattern on a substrate with changing irradiation positions of a plurality of beams with respect to the substrate in a sub-scanning direction by a predetermined amount, and deflecting the plurality of beams in a main scanning direction in each irradiation position of the sub-scanning direction, the drawing apparatus including: a detection unit configured to detect a defective beam from among the plurality of beams; and a control unit configured to control irradiation with a normal beam among the plurality of beams and the irradiation positions in the sub-scanning direction, wherein the control unit controls the irradiation such that, in a case in which the detection unit detects the defective beam, a normal beam is irradiated instead of the defective beam at a position that has been planned to be irradiated with the defective beam by changing an amount of change in the irradiation positions of the plurality of beams from the predetermined amount and, in a case in which the detection unit stops detecting the defective beam, the amount of change in the irradiation position of the plurality of beams is restored to the predetermined amount.

Further features of the disclosure will become apparent from the following description of exemplary embodiments with reference to the attached drawings.

### BRIEF DESCRIPTION OF THE DRAWINGS

FIG. 1 is a configuration diagram of a drawing apparatus according to a first embodiment.

FIG. 2 is a diagram illustrating a function of a main control unit.

FIG. 3 is a diagram illustrating an initial relative position between a wafer and electron beams.

FIGS. 4A to 4C are diagrams each illustrating a relationship between an irradiation state and a control instruction in a normal section.

FIGS. 5A to 5C are diagrams each illustrating a relationship between the irradiation state and the control instruction according to the first embodiment.

FIG. 6 is a flowchart for describing a compensation method.

FIGS. 7A to 7D are diagrams each illustrating a relationship between an irradiation state and a control instruction according to a second embodiment. Each of FIGS. 7A-7C illustrates a scanning locus of the electron beam.

FIG. 7D illustrates drawing instructions to the blanker of each of the electron beams.

### DESCRIPTION OF THE EMBODIMENTS

One disclosed aspect of the embodiments is applicable to a drawing apparatus which transfers a pattern to a wafer (i.e., to a substrate) by irradiating the wafer with a plurality of beams, such as charged particle beams, like a plurality of electron beams and ion beams, or a plurality of laser light beams. Hereinafter, an embodiment will be described with reference to a drawing apparatus which draws a pattern using a plurality of electron beams as an example.

### First Embodiment

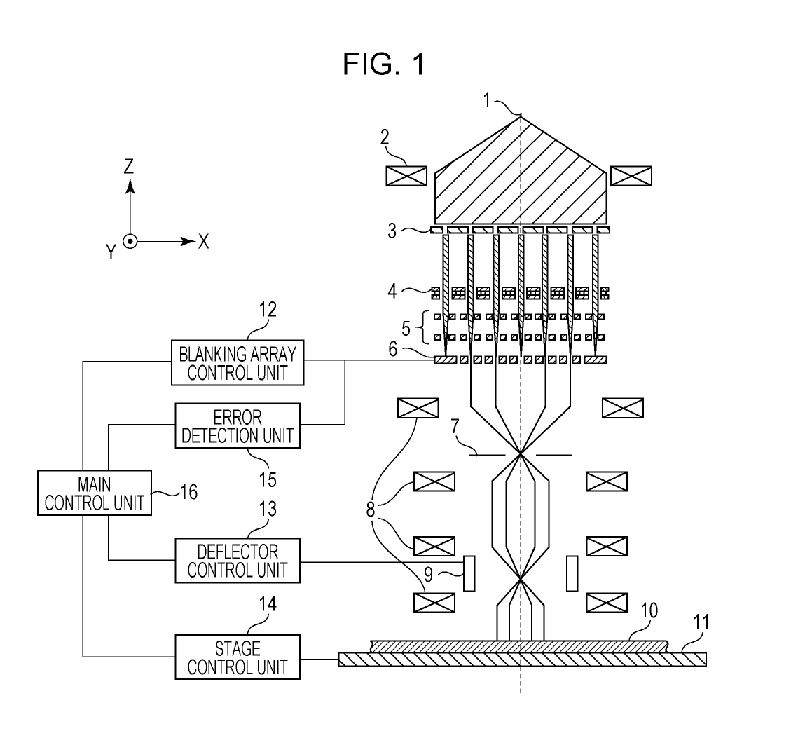

A configuration of a drawing apparatus according to a first embodiment will be described with reference to FIG. 1. This configuration is an apparatus configuration suitable for a case in which a defective electron beam (i.e., a defective beam) which is not able to irradiate due to an error in data transmission is detected, and compensation is performed with a normal electron beam (i.e., a normal beam) which is able to irradiate the area in which irradiation is not successfully performed.

An electron beam emitted from an electron source 1 is formed into a shape of a bunch of mutually parallel electron beams at a collimator lens 2 and the electron beams enter almost vertically to an aperture array 3 which has a plurality of openings. The aperture array 3 splits the entered electron beam into a plurality of electron beams. A lens array 4 is a collection of electrostatic lenses provided with a plurality of openings in a plate-shaped electrode. The lens array 4 converges each electron beam split by the aperture array 3. A multideflector 5 finely adjusts converging positions so that each electron beam can pass a blanking array 6.

The blanking array 6 is a collection of a plurality of blankers. The blanking array 6 switches existence of deflection with respect to the electron beams in accordance with existence of application of a voltage to a pair of electrodes of each blanker. In a case in which the blanker receives a drawing instruction of ON from a control unit 12, the electron beam is not deflected and made to pass through the opening of a diaphragm 7 as it is. On the other hand, in a case in which the blanker receives a drawing instruction of OFF, the electron beam is deflected and is shielded by the diaphragm 7. Lenses 8 are ring-shaped electrostatic lenses which form the electron beams so that the electron beams which passed the blanking array 6 are reduction-projected on the wafer 10 (i.e., the substrate).

A deflector 9 (a deflector) is constituted by a pair of electrode plates for a X axis and a pair of electrode plates for a Y axis (one of which pairs is not illustrated). The deflector 9 deflects a plurality of electron beams which passed the diaphragm 7 collectively in the same direction. Regarding the deflector 9, the deflector for the X axis and the deflector for the Y axis can be controlled independently. A wafer 10 is held by an unillustrated holding member and is placed on a stage 11 (i.e., a movable member). The stage 11 is movable in X, Y and Z directions in response to instructions from a control unit 14 while holding the wafer 10.

The control unit 12 which controls the blanking array 6 instructs existence of voltage application to each electrode of the blanking array 6. Therefore, a drawing instruction for instructing existence of irradiation to each electron beam is made. A control unit 13 which controls the deflector 9 instructs a deflection degree with respect to the deflector for the X axis and the deflector for the Y axis. The control unit 14 which controls a position of the stage 11 instructs a driving amount of the stage 11 to an actuator (not illustrated) for driving the stage 11.

A deflection width by the deflector 9 is very small as compared with the movement of the stage 11. A deflection direction by the X deflector is defined as a the main scanning direction (i.e., an X-axis direction) and a direction, of the movement of the stage 11, in which the electron beams irradiate the wafer 10 placed on the stage 11 with the deflection width (i.e., a predetermined deflection width) by the X deflector is defined as a sub-scanning direction (i.e., a Y-axis direction). A pattern is drawn line by line in the sub-scanning direction with the movement of the stage 11, adjustment of the irradiation position of the electron beams by the deflector 9 and existence of irradiation of the electron beams being in synchronization.

An error detection unit 15 is provided as a detection unit which detects a defective electron beam. The error detection unit 15 determines whether irradiation based on the drawing instruction issued by the control unit 12 can be performed. In the present embodiment, a defective electron beam caused due to an error in data transmission is detected based on a monitored result of transmission of data to each blanker.

Therefore, whether control data transmitted from the control unit 12 to each blanker of the blanking array 6 is transmitted correctly is sequentially monitored. When an error is detected, information about a position of the blanker at which a specified transmission error is caused, control data which has caused the error, a drawing position that should have been irradiated with the electron beam, and the like is transmitted as detection results to a main control unit 16 which will be described below.

A checksum system, a cyclic redundancy check system, and the like may be used as a detecting method of the error. A parity check system is more desirably used. The parity check system is suitable for a system that requires high speed processing as the system of the present embodiment for its characteristic that a mounting scale is small and processing is simple.

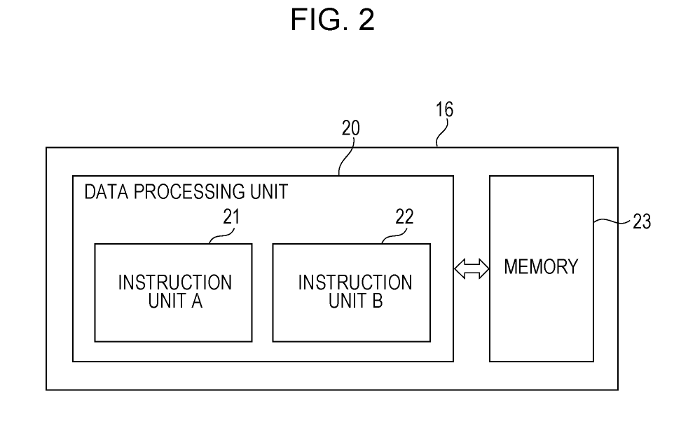

The main control unit 16 is connected to the control units 12, 13 and 14 and the error detection unit 15. The main control unit 16 is provided with a data processing unit 20 that includes a CPU, and memory 23 as illustrated in FIG. 2, and instructs a control content determined in the main control unit 16 to each of the control units 12, 13 and 14.

In the present embodiment, the control unit controls irradiation by the normal electron beam (i.e., the normal beam) and controls deflection of the electron beam in the main scanning direction. Further, the control unit controls such that the irradiation positions of a plurality of electron beams with respect to the wafer 10 in the sub-scanning direction are changed by a predetermined amount each time deflection is repeated in the main scanning direction (i.e., at predetermined timing). Therefore, the control units 12, 13, 14 and 16 correspond to the control units of the disclosure.

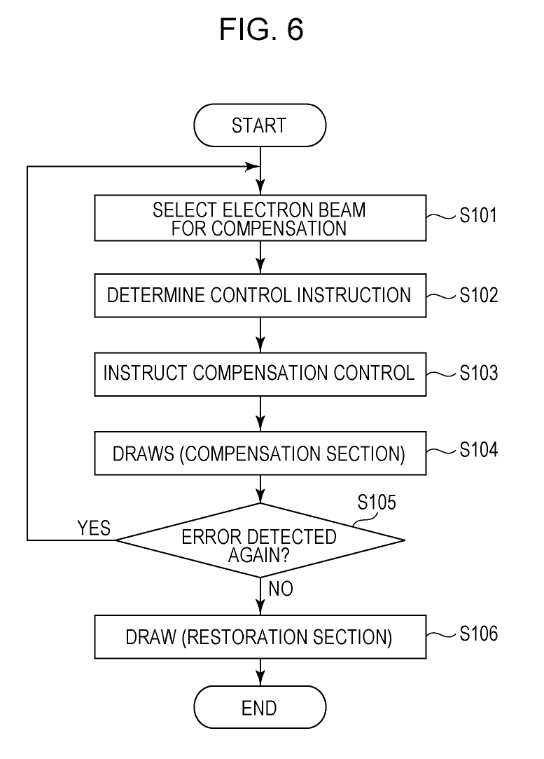

In the memory 23, a desired drawing pattern, an arrangement of each blanker of the blanking array 6, a program represented in the flowchart of FIG. 6 which will be described later, data of the control instruction created in the data processing unit 20 and the like are stored. The data processing unit 20 creates an instruction with which the drawing pattern stored in the memory 23 can be implemented.

An instruction unit A21 in the data processing unit 20 determines the drawing instruction (i.e., an irradiation instruction) to the blanking array 6. In a case in which a transmission error of data is detected by the error detection unit 15, an electron beam for compensating the electron irradiation to the area which has not been able to be irradiated due to the defective electron beam is selected. An instruction unit B22 determines a control instruction regarding a relative position between the irradiation position of the electron beam and the wafer 10. The control instruction from the instruction unit B22 is transmitted to the control unit 13 which controls the deflector 9 or the control unit 14 which controls driving of the stage 11.

With the configuration described above, it is possible to irradiate the wafer 10 with a plurality of electron beams. Further, it is possible to control existence of irradiation with each electron beam by the blanking array 6 and to form a latent image of a desired pattern to a resist (not illustrated) applied to the wafer 10.

### Drawing Method

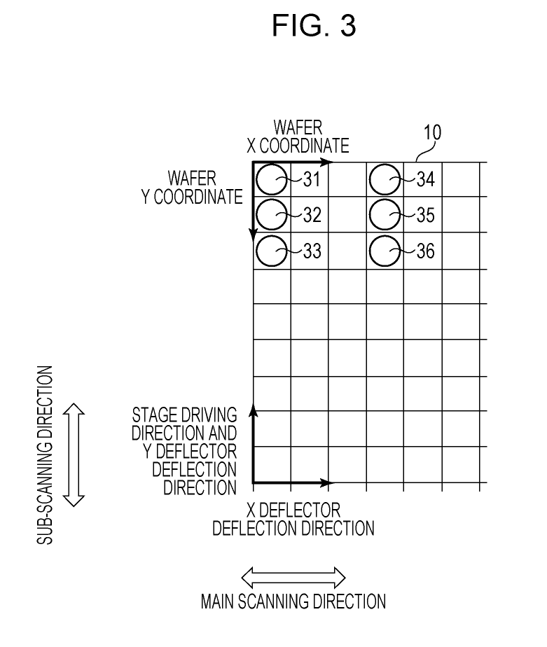

Next, a drawing method of a pattern on the wafer 10 will be described with reference to FIG. 3. FIG. 3 is a diagram illustrating a part of the wafer 10 seen from an irradiation side of the electron beams. Circles of solid lines in grid squares represent initial positions of six electron beams 31, 32, 33, 34, 35 and 36.

For the ease of explanation, a case in which three electron beams 31, 32 and 33 are located in three grid squares arranged continuously in a Y axis direction which corresponds to a sub-scanning direction and electron beams 34, 35 and 36 are continuously arranged at positions separated from the electron beams 31, 32 and 33 by three grid squares in an X axis direction which corresponds to a main scanning direction will be described as an example. One grid square represents the minimum unit of a drawing area. When one electron beam is irradiated in one grid square at certain time, a latent image is formed in the grid square.

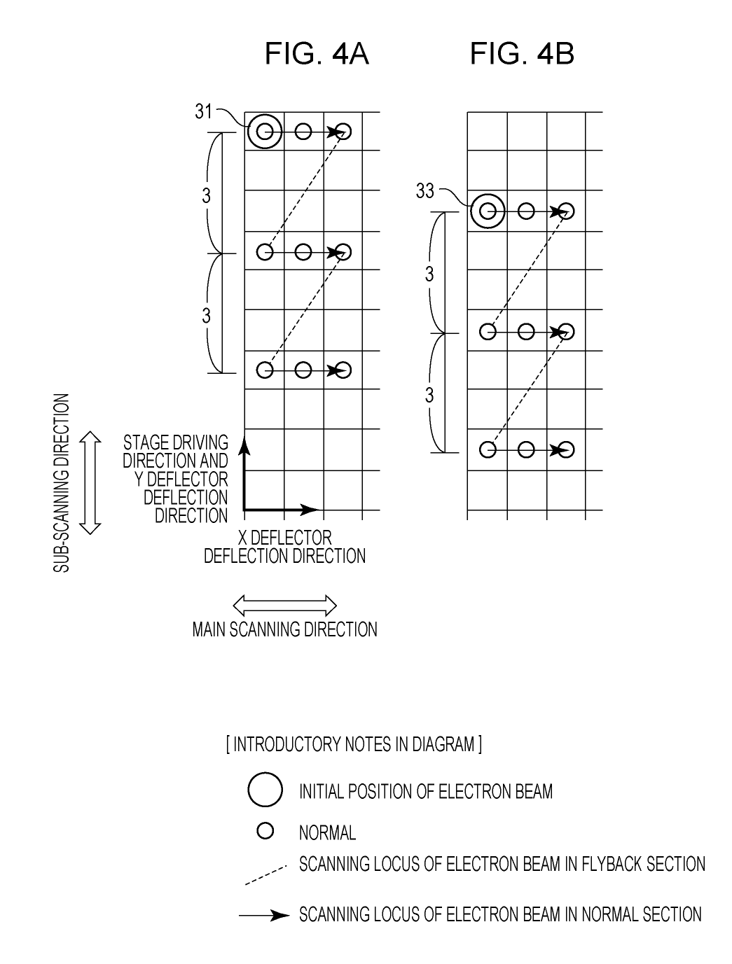

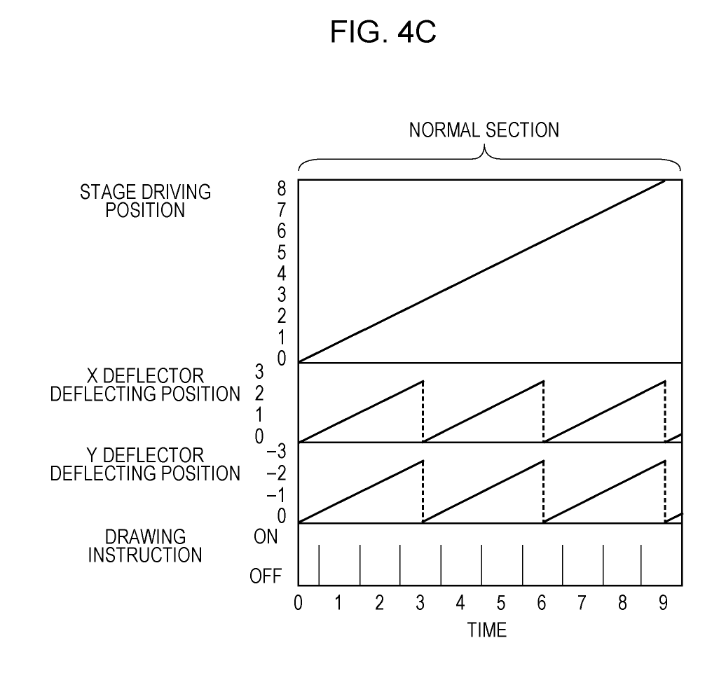

A line of drawing is performed from one end to the other end of the wafer with a width of the line in the drawing which being a deflection width for three grid squares formed by three electron beams. At this time, a desired pattern is drawn in a drawing area of the wafer 10 by drawing in the X-axis direction which is the main scanning direction. Hereinafter, a drawing method of a normal state in which no error is detected will be described with reference to FIGS. 4A to 4C.

FIG. 4A and FIG. 4B illustrate the same area on the wafer 10 in two different figures. FIG. 4A illustrates a scanning locus of an electron beam 31 in FIG. 3 and FIG. 4B illustrates a scanning locus of an electron beam 33 in FIG. 3. Each large circle represents an initial position of each electron beam and each small circle represents a position at which normal irradiation is performed.

A time section in which a drawing instruction for a normal state and control instructions to the deflector 9 and to the stage 11 are issued from the main control unit 16 is referred to as a normal section. In the normal section, as a result of the relative movement of the electron beam and the wafer 10, the irradiation position is changed so that the electron beams 31 and 33 are irradiated with +3 grid squares in the X-axis direction which is the main scanning direction at each 3 time. When the electron beams are irradiated with +3 grid squares, the electron beams 31 and 33 proceed by −3 grid squares in the X-axis direction and the Y-axis direction in a flyback section.

The flyback section refers to the time after the electron beam is deflected once in a predetermined deflection width in the X-axis direction before next deflection operation is performed, and refers to the time section in which no electron beam is irradiated. FIG. 4A and FIG. 4B illustrate a state in which a pattern is drawn in the sub-scanning direction in a width of three grid squares while making the electron beam repeat these operations using the deflector 9 and the stage 11.

Control instruction values of the drawing corresponding to FIGS. 4A and 4B are illustrated in FIG. 4C. A horizontal axis in FIG. 4C represents the time. One time section represents time that the electron beam requires to scan one grid square. A vertical axis represents, from above, a drawing instruction value from the control unit 14 to the stage 11, a control instruction value from the control unit 13 to the X deflector and the Y deflector, and a control instruction value from the control unit 12 to the blanking array 6 in this order. It is represented that each time the control instruction value increments by one, one grid square is scanned.

The drawing instruction in each time is all turned ON and corresponds to the states illustrated in FIGS. 4A and 4B in which the electron beams are irradiated all the grid squares. In a case in which a drawing instruction to turn OFF is issued from the control unit 12, the blanking array 6 deflects the electron beam and the wafer 10 is not irradiated.

In a case in which the instruction values to all of the X deflector, the Y deflector and the stage 11 are 0, the electron beams 31 and 33 are in the initial positions. The instruction value to the X deflector represents that the electron beam repeats the operation to restore to the original position through the flyback section each time the electron beams 31 and 33 are deflected by +3 grid squares in the X-axis direction in 3 times. The instruction value to the Y deflector represents that the electron beam repeats the operation to restore to the original position through the flyback section each time the electron beams 31 and 33 are deflected by −3 grid squares in the Y-axis direction in 3 times. The instruction value to the stage 11 represents that the stage 11 monotonously increments by +1 grid square in the Y-axis direction in each 1 time.

The relative position between the irradiation position of the electron beam and the wafer 10 in the sub-scanning direction is defined by the instruction value to the Y-axis direction, i.e., the sum of the instruction value to the Y deflector and to the stage 11. Therefore, in the case of the instruction value illustrated in FIG. 4C, the relative position is changed by 3 grid squares (i.e., a predetermined amount) in the sub-scanning direction in the flyback section each time the electron beam is deflected by +3 grid squares in the main scanning direction.

In response to the above-described control instruction to the deflector 9 and to the stage 11, in the normal section, the electron beam is irradiated as shown in FIGS. 4A and 4B while the relative position between the irradiation position of the electron beam and the wafer 10 in the sub-scanning direction being changed by a predetermined amount in every flyback section. In accordance with a desired drawing pattern, switching of ON and OFF of the electron beam is performed in each blanker.

### Compensation Method at the Time of Defective Irradiation

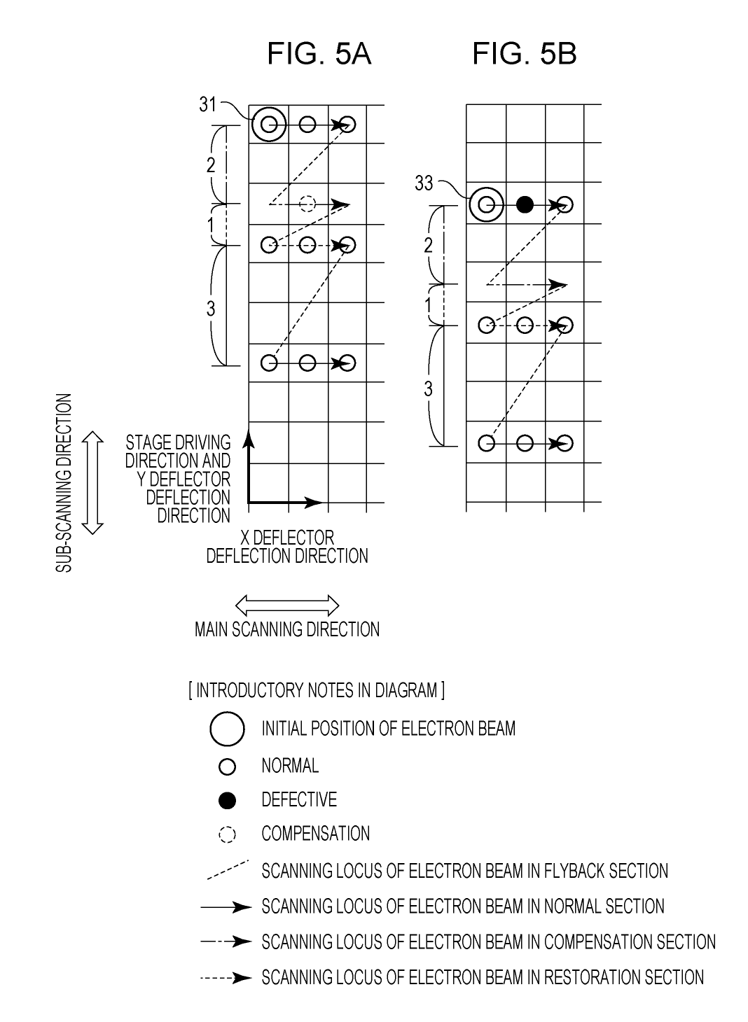

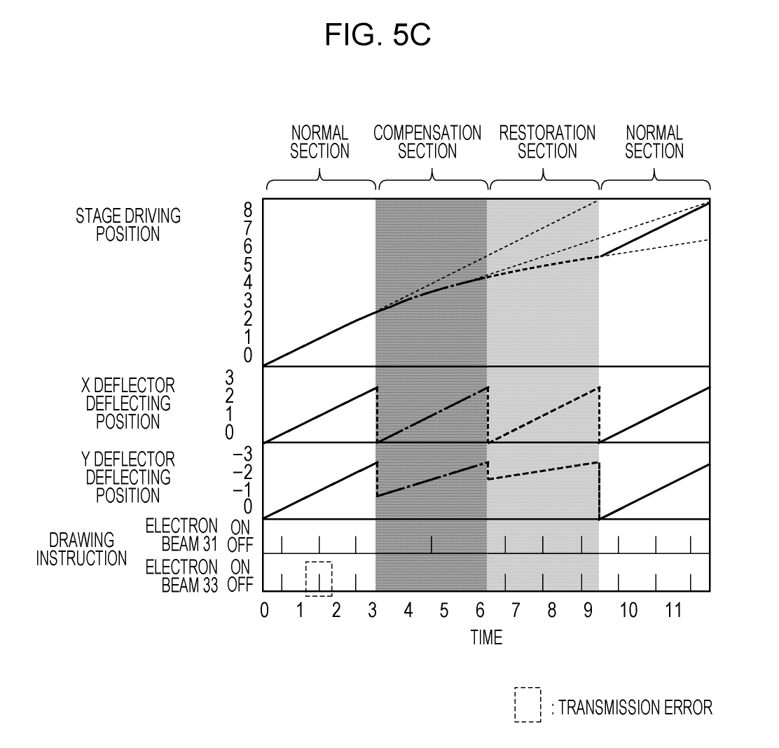

Next, a compensation method in a case in which a defective electron beam is caused temporarily due to a transmission error of data while a pattern according to the present embodiment is being drawn will be described with reference to FIGS. 5A to 5C and the flowchart illustrated in FIG. 6.

FIG. 5A illustrates a scanning locus of the electron beam 31 and FIG. 5B illustrates a scanning locus of the electron beam 33. FIG. 5C illustrates a control instruction value to the deflector 9, a control instruction value to the stage 11, and a drawing instruction to a blanker which makes the electron beams 31 and 33 pass through. In FIGS. 5A, 5B and 5C, the same line type represents the same section (i.e., the above-described normal section, a later-described compensation section and a later-described restoration section).

During drawing in each section, the error detection unit 15 monitors whether the drawing instruction is transmitted normally from the control unit 12 to each blanker of the blanking array 6.

The program illustrated in a flowchart of FIG. 6 is stored in the memory 23. The main control unit 16 reads the program and instructs each of the control units 12, 13 and 14 to execute the program. The timing at which the flowchart illustrated in FIG. 6 is started is when an error of data transmission is detected in the error detection unit 15. In the present embodiment, a case in which the electron beam 33 is not able to be irradiated in section of times 1 to 2 in spite that the same control instruction in the normal section as that of FIG. 4C has been issued in a section of times 0 to 3 will be described as an example. In FIG. 5B, a portion at which irradiation is not performed due to a defective electron beam (i.e., a defective beam) caused by a transmission error of data is represented by a black circle.

In a case in which an error is detected, the data processing unit 20 of the main control unit 16 determines a control instruction for compensation in accordance with information transmitted from the error detection unit 15. First, a normal electron beam that performs irradiation for compensation is determined (S101). As the normal electron beam that is irradiated instead of the defective electron beam 33, an electron beam located behind the electron beam 33 in the drawing direction may be selected. The electron beam located behind the electron beam 33 means an electron beam which scans a position of a sub-scanning direction component of the defective electron beam 33 later than the defective electron beam 33. Although the electron beams that can implement irradiation for compensation exist in the front and behind the electron beam 33, the electron beam located behind the electron beam 33 is used instead of the electron beam located in front of the electron beam 33 because reduction in a decrease in the throughput can be suppressed.

Therefore, in the case of the present embodiment, either of the electron beam 31 or 32 located immediately behind the electron beam 33 among the electron beams 31, 32, 34, 35 and 36 illustrated in FIG. 3 may be selected. Here, a case in which the electron beam 31 is selected is described as an example. In a case in which a deflectable range of the X deflector is wide, the electron beams 34 and 35 located diagonally behind the electron beam 33 may be used.

In order to be able to irradiate, with the electron beam 31, the grid square that has not been able to be irradiated with the electron beam 33, the instruction unit B22 determines the control instruction value which determines the relative position between the electron beam and the wafer 10 (S102). In particular, the control instruction value to the stage 11 and the control instruction value to the deflector 9 are determined and, an amount of change in the relative positions among the wafer 10 and a plurality of electron beams are changed so that the electron beam 31 which performs compensation passes through an area that has not been able to be irradiated due to the defective electron beam 33 (i.e., a position that has been planned to be irradiated with a defective beam). Further, the instruction unit A21 determines a drawing instruction to each blanker.

The instruction values determined in S102 are transmitted to the control units 12, 13 and 14 from the data processing unit 20 (S103). The control instruction values for compensation transmitted in S103 are illustrated in section of times 3 to 9 of FIG. 5C. By inserting a special control instruction with respect to the control instruction in the normal section, a failure in drawing due to occurrence of a defective electron beam 33 is prevented. Drawing in the compensation section is performed in the section of times 3 to 6 (S104).

In the compensation section, in accordance with the control instruction determined in S102, the relative position between the irradiation position of the electron beam and the wafer 10 is controlled. In the normal section, the Y deflector moves the electron beam by −3 and moves the stage 11 by +3 in 3 times while, in the compensation section, the Y deflector moves the electron beam by −2 and moves the stage 11 by +2. By conducting the control of the electron beam by the deflector and the control of the stage simultaneously, the amount of change in the relative position between the wafer 10 and the irradiation position of the electron beam in the sub-scanning direction is changed from 3 to 2 when the normal section is switched to the compensation section.

That is, the amount of change in the relative position between the wafer 10 and the irradiation position of the electron beam is changed at the timing at which the control instruction value to the X deflector restores from a certain value to 0. The control instruction value of the X deflector is made a repetition of 0 to 3 in order to avoid complication of data processing, but the present embodiment is not restrictive.

The control unit 12 transmits a drawing instruction such that, in the compensation section, the electron beam 31 irradiates an area that has not been irradiated with the electron beam 33 and other electron beams do not perform irradiation. Therefore, no drawing instruction is issued to the electron beam other than the electron beam 31 that contributes to the compensation and irradiation is not performed.

In the compensation section, an error detection unit 15 also determines whether an error is detected again (S105). If it is determined that an error has been detected (YES), the flowchart which begins from S101 is repeated. If it is determined that no error has been detected (NO), drawing in accordance with the restoration section is performed in the section of times 6 to 9 (S106).

The restoration section is a section for restoring to the control corresponding to the normal section after finishing the drawing in the compensation section.

Therefore, the relative position between the irradiation position of the electron beam and the wafer 10 is moved by +3 in the X-axis direction and by −1 in the Y-axis direction. In the restoration section, drawing instructions are issued to the electron beams 31 to 36 and all the electron beams are made to irradiate in accordance with the drawing instructions.

Description of the flowchart illustrated in FIG. 6 is completed. After time 9, drawing is repeated while the amount of change in the relative position between the irradiation position of the electron beam and the wafer 10 is repeated in the same manner as in the normal section. When an error is detected again, the operations from S101 to S106 are performed repeatedly and an influence by the defective electron beam is compensated sequentially using the normal electron beam.

According to the present embodiment, even in a case in which a defective electron beam is detected temporarily while forming a pattern latent image to a certain line on the wafer 10, by changing the amount of change in the sub-scanning direction in accordance with the information about the defective electron beam, it is possible to irradiate, with the normal electron beam, a position that is not able to be irradiated due to a defective electron beam.

In the case of the present embodiment, compensation is performed while the stage 11 is continuously driven in the sub-scanning direction without being temporarily stopped or driven in the opposite direction again, it is possible to significantly reduce a decrease in the throughput. While driving the stage 11, by decreasing the speed of the stage 11 in the compensation section and in the restoration section, an effect of preventing the control of the electron beam from becoming unstable due to an unnecessarily increased deflection amount of the Y-axis may be produced.

In the case in which the defective electron beam turn to be the normal electron beam, the control instruction restores to the control instruction in the normal section. Therefore, there is no need that the electron beam scans the wafer 10 more than necessary. This produces an effect of reducing a decrease in the throughput. In the present embodiment, compensation with the normal electron beam is performed in a period after the defective electron beam is detected and before scanning of the line in which that electron beam is detected is finished for the first time (i.e., before a direction in which the irradiation positions of a plurality of beams are changed by a predetermined amount is inverted for the first time). In this manner, it could be possible to reduce a decrease in the throughput as compared with a case in which an optical system scans almost all the areas on the wafer 10 twice to compensate the same.

### Second Embodiment

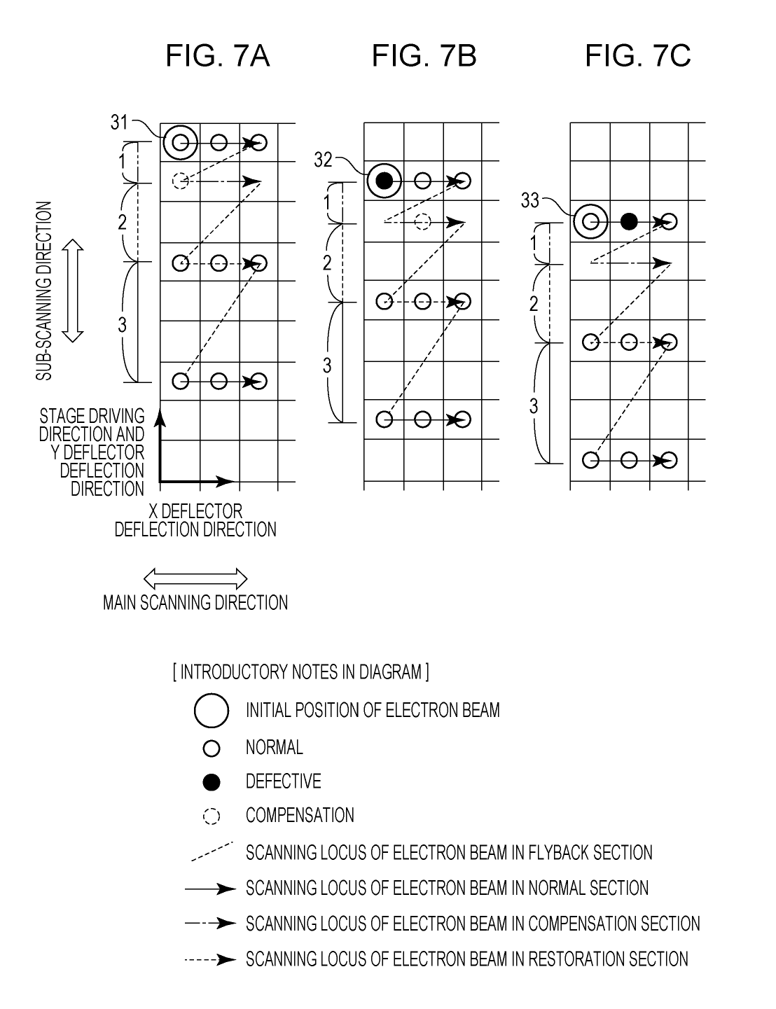

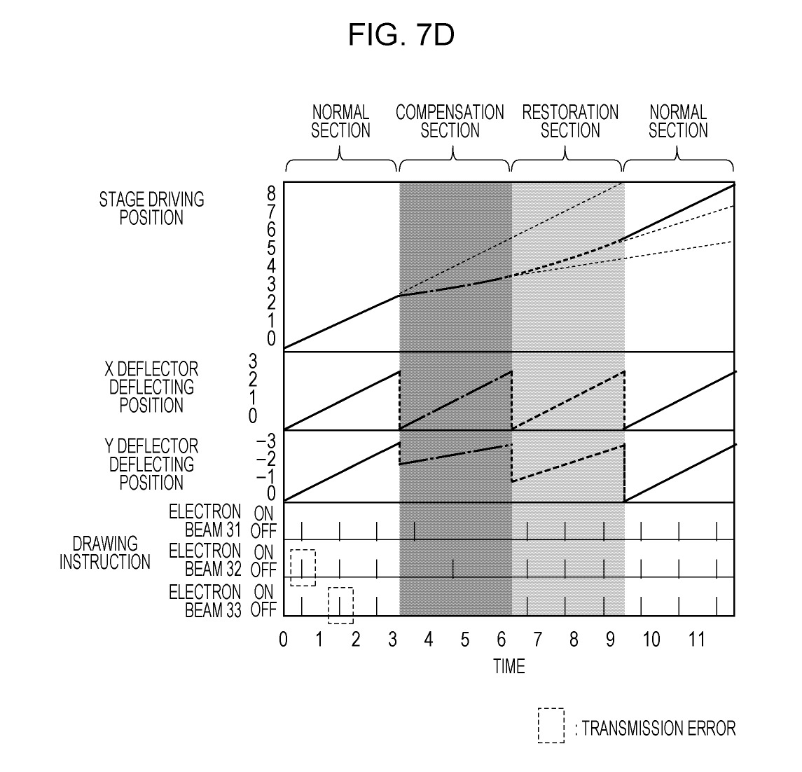

In the present embodiment, a compensation method in a case in which an error in data transmission to two electron beams is detected in the same drawing apparatus as that of the first embodiment will be described with reference to FIGS. 7A to 7C. FIG. 7A illustrates a scanning locus of the electron beam 31, FIG. 7B illustrates a scanning locus of the electron beam 32, and FIG. 7C illustrates a scanning locus of the electron beam 33. FIG. 7D illustrates drawing instructions to the blanker of each of the electron beams 31, 32 and 33 and the control instruction values to the deflector 9 and to the stage 11. The flow of compensation in the case in which an error is detected is the same as that of the flowchart illustrated in FIG. 6.

In a case in which an error occurs in the electron beam 32 in the section of times 0 to 1 and an error occurs in the electron beam 33 in the section of times 1 to 2, a compensation section is provided in the section of times 3 to 6. The instruction unit A21 selects an electron beam for compensation so that the area which has not been able to be irradiated with the electron beam 32 is compensated with the electron beam 31 and the area which has not been able to be irradiated with the electron beam 33 is compensated with the electron beam 32.

The instruction unit B changes a predetermined amount of change in the relative position between the irradiation position of the electron beam and the wafer 10 in the sub-scanning direction in the compensation section, and generates data of the control instruction in the compensation section. In the case of the present embodiment, in the compensation section, the control instruction is changed into a control instruction in which the Y deflector is moved by −1 in 3 time sections and the position of the stage 11 by +1 in the Y direction in 3 time sections. The instruction unit A21 issues a drawing instruction to the control unit 12 so that the electron beam 31 draws in the section of times 3 to 4, the electron beam 32 draws in the section of times 4 to 5, and other electron beams do not draw.

When no defective electron beam occurs in the compensation section, control in the restoration section is performed. In 3 time sections, the control instruction is switched to a control instruction in which the Y deflector is moved by −2 and the position of the stage 11 is moved by +2 in the Y direction and the control instruction is again restored to that of the normal section.

The electron beam 32 that once has become a defective electron beam is used to compensate for the defective irradiation of the electron beam 33. This is because the error in the data transmission is temporary. In a case in which it is not desirable to use the electron beam 32 again, it is also possible to compensate the area which has not been able to be irradiated with the electron beam 32 and the electron beam 33 by only using the electron beam 31. In that case, two compensation sections are provided continuously.

According to the second embodiment, by changing the amount of change in the irradiation position of the electron beam with respect to the wafer 10 in the sub-scanning direction, even in a case in which a plurality of defective electron beams are detected, it is possible to compensate the drawing in the area which is not able to be irradiated due to the defective electron beams, while reducing a decrease in the throughput.

### Third Embodiment

In the first and the second embodiments, an example in which a defective electron beam is detected in accordance with an error in data transmission has been detected. In the present embodiment, a method for detecting a defective electron beam (i.e., a defective beam) in a case in which a beam is not able to pass between electrodes of a blanker due to adhesion of a substance which prevents irradiation of the electron beam, such as dust, and drawing becomes impossible will be described.

In order to detect such a defective electron beam, there is a method for providing an electrostatic capacity sensor (not illustrated) in each blanker. If the error detection unit 15 is connected to each electrostatic capacity sensor, it is possible to determine whether the corresponding electron beam can irradiate normally from an electrostatic capacity value of each sensor, i.e., whether the corresponding electron beam is defective or normal. Since the method for compensating the drawing after the detection of the defective electron beam is the same as those of the first and the second embodiments, description thereof will be omitted.

### Fourth Embodiment

A method for detecting a defective electron beam (i.e., a defective beam) in a case in which a desired voltage is not able to be applied to the lens array 4 due to deterioration over time and, therefore, drawing becomes impossible will be described.

In order to detect such a defective electron beam, there is a method for providing a current probe (not illustrated) in the vicinity of an opening of each lens of the lens array 4. If each current probe is connected to the error detection unit 15, it is possible to detect a defective electron beam by measuring a current value of the current probe which responds to a change in a magnetic field accompanying a change in a passage state of the electron beam. Since the method for compensating after the detection of the defective electron beam is the same as those of the first and the second embodiments described above, description thereof will be omitted.

### Other Embodiments

Although an example in which drawing is temporarily performed in the compensation section and in the restoration section and then the drawing instruction is restored to the normal drawing instruction is illustrated in each embodiment described above, these embodiments are not restrictive. For example, in a case in which a predetermined times or more defective electron beams occur, the defective electron beams are not used and drawing may be performed while repeating the normal section and the compensation section for 3 time sections.

It is because that high defective frequency means a high possibility of occurrence of errors thereafter. Further, it is because there is an advantage that data transmission is less complicated if drawing is continued periodically using once generated data for compensation rather than performing data processing whenever an error occurs.

The embodiments in which the stage 11 is sequentially scanned are illustrated in FIGS. 4A to 4C, 5A to 5C and 7A to 7C. However, the disclosure is applicable to a control method in which neither the Y deflector nor the stage 11 is moved during scanning of the electron beam by the X deflector, but the stage 11 is moved stepwise in every 3 times. In this case, a highly precise synchronous operation between the Y deflector and the stage 11 is unnecessary. Therefore, there are effects that an irradiation position can be defined with high precision and that, since the Y deflector is unnecessary, the configuration of the drawing apparatus can be made simple.

A method in which, when a defective electron beam occurs, the drawing in the compensation section and in the restoration section between the drawing in the predetermined normal section has been described, but this method is not restrictive. It is also possible to provide a normal electron beam with a drawing instruction to an area in which drawing can be performed newly while compensating an area which has not been able to be irradiated due to a defective electron beam by changing a predetermined amount of change in the relative position between the irradiation position of the electron beam and the wafer 10. This is because it is possible to further reduce a decrease in the throughput by regenerating drawing data after the compensation section and performing irradiation for compensation and irradiation on a new grid square.

It is only necessary that the control unit of an embodiment includes a portion that controls irradiation with a normal beam, deflection of a beam in the main scanning direction, and relative movement between the irradiation position of the beam in the sub-scanning direction and the wafer 10. Therefore, the control units 12, 13, 14 and 16 in each embodiment described above are not necessarily included.

For example, in a case in which there is a unit to control switching of existence of irradiation to the normal electron beam and control adjustment of the irradiation amount by any techniques other than the blanking array 6, that unit is included as a control unit of an embodiment.

As another detecting method of the defective electron beam, other than the detecting method of the error described in each embodiment described above, an electron beam which has not been able to normally irradiate may be detected by detecting secondary electrons produced from each irradiation area near the wafer 10.

Although examples in which an electrostatic lens is used as a lens for shaping the electron beam are described in the first to the fourth embodiments, the disclosure is applicable also to a charged particle beam drawing apparatus in which an electromagnetic lens is used instead of an electrostatic lens. The defective electron beam does not necessarily mean an electron beam which is not used for the irradiation but the defective electron beam may mean those are not able to irradiate with a desired irradiation amount and are not able to perform drawing. For example, the irradiation amount of the electron beam may be detected by detecting secondary electrons produced from each irradiation area near the wafer 10 and, if the irradiation amount is less than a desired irradiation amount, the remaining necessary irradiation amount may be provided by other normal electron beams.

### Manufacturing Method of Article

A manufacturing method of an article, such as a device or a reticule in an embodiment, includes a process of irradiating a wafer with a beam, such as an electron beam, by a drawing apparatus described in each embodiment and a process of developing a wafer 10 on which a pattern is drawn. The method may include other known processes (e.g., oxidization, film formation, vapor deposition, doping, smoothing, etching, resist removing, dicing, bonding and packaging).

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2013-261508 filed Dec. 18, 2013, which is hereby incorporated by reference herein in its entirety.

What is claimed is:

1. A drawing apparatus which draws a pattern on a substrate with changing irradiation positions of a plurality of beams with respect to the substrate in a sub-scanning direction by a predetermined amount, and deflecting the plurality of beams in a main scanning direction in each irradiation position of the sub-scanning direction, the drawing apparatus comprising:
a detection unit configured to detect a defective beam from among the plurality of beams; and
a control unit configured to control irradiation with a normal beam among the plurality of beams and the irradiation positions in the sub-scanning direction,
wherein the control unit controls the irradiation such that, in a case in which the detection unit detects the defective beam, a normal beam is irradiated instead of the defective beam at a position that has been planned to be irradiated with the defective beam by changing an amount of change in the irradiation positions of the plurality of beams from the predetermined amount and, in a case in which the detection unit stops detecting the defective beam, the amount of change in the irradiation position of the plurality of beams is restored to the predetermined amount.

2. The drawing apparatus according to claim 1, wherein the deflection is repeatedly performed with a predetermined deflection width, and the control unit changes the amount of change after deflecting once with the predetermined deflection width and before next deflection operation is started.

3. The drawing apparatus according to claim 1, wherein the control unit irradiates, with the normal beam instead of the defective beam, the position that has been planned to be irradiated with the defective beam after the detection unit detects the defective beam and before a direction in which the irradiation positions of the plurality of beams are changed with respect to the substrate in sub-scanning direction by a predetermined amount is inverted for the first time.

4. The drawing apparatus according to claim 1, wherein the control unit performs operation to change the irradiation positions of the plurality of beams with respect to the substrate in the sub-scanning direction by the predetermined amount at predetermined timing.

5. The drawing apparatus according to claim 1, wherein the control unit uses the normal beam instead of the defective beam, the normal beam located behind the defective beam in the sub-scanning direction.

6. The drawing apparatus according to claim 1, wherein the control unit uses the normal beam instead of the defective beam, the normal beam located diagonally behind the defective beam.

7. The drawing apparatus according to claim 1, wherein the control unit uses the normal beam instead of the defective beam, the normal beam located immediately behind the defective beam in the sub-scanning direction.

8. The drawing apparatus according to claim 1, wherein the control unit changes the amount of change in the irradiation positions in the sub-scanning direction by controlling at least one of a deflector which deflects the plurality of beams and a movable member which moves withholding the substrate.

9. The drawing apparatus according to claim 1, wherein the detection unit detects the defective beam in accordance with existence of an error in transmission of data about an irradiation instruction of the plurality of beams.

10. The drawing apparatus according to claim 1, wherein the beam is a charged particle beam, and the detection unit detects the defective beam caused by a substance that prevents irradiation of the plurality of beams by measuring electric capacity between electrodes through which each beam passes among the plurality of beams.

11. The drawing apparatus according to claim 1, wherein the plurality of beams are charged particle beams, and the detection unit detects the defective beam by measuring a current value at an opening of an electrode plate through which each beam passes among the plurality of beams.

12. A drawing apparatus which draws a pattern on a substrate with changing irradiation positions of a plurality of beams with respect to the substrate in a sub-scanning direction by a predetermined amount, and deflecting the plurality of beams in a main scanning direction in each irradiation position of the sub-scanning direction, the drawing apparatus comprising:
a detection unit configured to detect a defective beam from among the plurality of beams; and
a control unit configured to control irradiation with a normal beam among the plurality of beams and the irradiation positions in the sub-scanning direction,
wherein the control unit controls the irradiation such that, in a case in which the detection unit detects the defective beam, a normal beam is irradiated instead of the defective beam at a position that has been planned to be irradiated with the defective beam by changing an amount of change in the irradiation positions of the plurality of beams from the predetermined amount and, in a case in which the detection unit stops detecting the defective beam, the amount of change in the irradiation position of the plurality of beams is approximated to the predetermined amount.

13. A drawing method in which a pattern is drawn on a substrate with changing irradiation positions of a plurality of beams with respect to the substrate in a sub-scanning direction by a predetermined amount, and deflecting the plurality of beams in a main scanning direction in each irradiation position of the sub-scanning direction, the method comprising:
detecting a defective beam from among the plurality of beams;
after detecting the defective beam, irradiating a normal beam instead of the defective beam at a position that has been planned to be irradiated with the defective beam by changing an amount of change in the irradiation positions of the plurality of beams from the predetermined amount; and
after detecting that the defective beam becomes a normal beam, restoring the amount of change in the irradiation positions of the plurality of beams to the predetermined amount.

14. A manufacturing method of an article, comprising:
irradiating a substrate with a beam using a drawing apparatus which draws a pattern on a substrate with changing irradiation positions of a plurality of beams with respect to the substrate in a sub-scanning direction by a predetermined amount, and deflecting the plurality of beams in a main scanning direction in each irradiation position of the sub-scanning direction; and
developing the substrate, wherein:
the drawing apparatus includes
a detection unit configured to detect a defective beam from among the plurality of beams and
a control unit configured to control irradiation with a normal beam among the plurality of beams and the irradiation positions in the sub-scanning direction; and
the control unit controls the irradiation such that, in a case in which the detection unit detects a defective beam, a normal beam is irradiated instead of the defective beam at a position that has been planned to be irradiated with the defective beam by changing an amount of change in the irradiation positions of the plurality of beams from the predetermined amount and, in a case in which the detection unit stops detecting the defective beam, the amount of change in the irradiation position of the plurality of beams is restored to the predetermined amount.
